(19) United States
(12) Patent Application Publication
(10) Pub. No.: US 2013/0045597 A1
(43) Pub. Date: Feb. 21, 2013

(54) LIQUID COMPOSITION FOR CLEANING SEMICONDUCTOR SUBSTRATE AND METHOD OF CLEANING SEMICONDUCTOR SUBSTRATE USING THE SAME

(71) Applicants: Kyoko Kamada, Tokyo (JP); Kenji Yamada, Tokyo (JP); Hiroshi Matsunaga, Tokyo (JP)

(72) Inventors: Kyoko Kamada, Tokyo (JP); Kenji Yamada, Tokyo (JP); Hiroshi Matsunaga, Tokyo (JP)

(73) Assignee: MITSUBISHI GAS CHEMICAL COMPANY, INC., Tokyo (JP)

(21) Appl. No.: 13/695,552

(22) PCT Filed: Oct. 18, 2011
(86) PCT No.: PCT/JP11/73948

§ 371 Date: Oct. 31, 2012

(30) Foreign Application Priority Data
Nov. 19, 2010 (JP) 2010-258970

(51) Int. Cl. C11D 17/00; H01L 21/304; H01L 21/306

(52) U.S. Cl. 438/692; 510/175; 257/E21.23

(57) ABSTRACT

[Problems] An object of the present invention is to provide a cleaning liquid composition which removes residual liquid and contaminants after chemical-mechanical polishing (CMP) of the surface of a semiconductor substrate in the production process of a semiconductor circuit device; and a cleaning method using the cleaning liquid composition.

[Means for Solution] The cleaning liquid composition according to the present invention comprises a quaternary ammonium hydroxide, 1-ethinyl-1-cyclohexanol, a complexing agent, diethylenetriamine pentamethylene phosphonate and water and has a pH of 9 to 13. By cleaning a wiring material with the cleaning liquid composition according to the present invention, the wiring material can be protected against contamination, corrosion, oxidation and generation of foreign substance that are originated from the production process of a semiconductor circuit device or the environment, so that a clean wiring surface can be obtained.

### TECHNICAL FIELD

The present invention relates to a cleaning liquid composition used for cleaning a semiconductor substrate. More particularly, the present invention relates to a cleaning liquid composition used for, in a production process of a semiconductor circuit device, removing residual liquid and contaminants remaining on the substrate surface after chemical-mechanical polishing (CMP); protecting the wiring surface, which is exposed after CMP and contains not less than 80% by weight of copper, from contamination, corrosion and oxidation that are originated from the production process of a semiconductor circuit composition or environment; and suppressing the generation of foreign substance on the metal surface, thereby obtaining a clean wiring surface. The present invention also relates to a method of producing a semiconductor circuit device using the cleaning liquid composition.

### BACKGROUND ART

Semiconductor circuit devices have been more and more highly integrated, requiring miniaturization of the patterning dimensions. In association with this, although an alloy containing aluminum as a major component has been conventionally used in circuit wirings and electrode materials, the resistance of such alloy is too high for it to be used as a wiring material of highly integrated semiconductor circuit device; therefore, there arose problems of, for example, a reduction in the circuit response rate due to wire delay, an increase in the heat generation, electromigration caused by an increase in the current density. Thus, in order to avoid these problems, wiring materials in which copper having lower electrical resistance and superior migration property as compared to an alloy containing aluminum as a major component or a copper alloy containing not less than 80% by weight of copper is used (hereinafter, referred to as “copper wiring material”) have been developed and widely utilized.

In cases where copper or a copper alloy containing not less than 80% by weight of copper is used as a wiring material, a wiring formation technology called damascene method, in which a wiring-shaped groove is formed in an interlayer insulating film and a metal such as copper wiring material is embedded therein, is employed.

In the damascene method, after a groove-like pattern is formed in the above-described interlayer insulating film, in order to prevent copper contained in the copper wiring material from diffusing into the insulating material, a thin diffusion-preventing film is formed to uniformly cover the thus patterned interlayer insulating film. As a method of forming such film, a film-forming method such as sputtering method or chemical vapor deposition method (CVD method) is commonly performed to form a diffusion-preventing film called barrier layer or barrier metal as an insulating material such as a patterned interlayer insulating film.

After the formation of the above-described barrier layer, in order to form a copper wiring, a seed layer of an electroconductive metal which preferably contains copper is deposited. Such seed layer of copper is formed by a variety of film-forming methods such as sputtering method, CVD method and electroplating and a substrate for bulk film formation of copper is formed. After bulk copper is formed into a film, excess copper is removed by CMP method.

In the CMP method, a wafer is press-adhered to an abrasive cloth while supplying thereto a mixed slurry of abrasive particles and a chemical agent and excess material is removed by rotating the resultant to utilize chemical and physical actions in combination, thereby achieving a finely flattened substrate surface. After the CMP, the substrate surface is contaminated by the particles contained in the slurry, which are represented by alumina, silica and cerium oxide particles, the constituents of the surface to be polished or metal impurities originated from the chemicals contained in the slurry. These contaminants cause, for example, a defective pattern and poor adhesion property and electrical characteristics; therefore, they need to be completely removed before advancing to the next step.

In the meantime, copper which is useful as a wiring material has a problem in that, upon coming into contact with an insulating material such as an interlayer insulating film, copper contained in copper wiring material diffuses into the insulating material to cause a reduction in the insulating property thereof. Further, not only a copper wiring material is oxidized very easily and the surface thereof thus easily becomes an oxide, but also a copper wiring material is easily corroded in an aqueous solution used for wet-etching, cleaning, rinsing and the like; therefore, attention needs to be paid when handling such copper wiring material.

After removing excess copper wiring material by the CMP method and flattening the copper wiring surface, a method in which a diffusion-preventing film commonly called cap layer is formed thereon by sputtering method, CVD method or the like to cover the copper wiring is performed because of the above-described problem caused by copper properties. The copper wiring material to be covered by a diffusion-preventing film called cap layer is in an exposed state until it is covered by this diffusion-preventing film. This copper in an exposed state is easily oxidized by the action of oxygen in the air and an oxidized layer is formed on the surface of the copper wiring material before it is covered by a diffusion-preventing film. Further, depending on the standby time before advancing to the step of forming a diffusion-preventing film, the exposed surface of the copper wiring material may be considerably oxidized to, for example, generate a foreign substance or cause contamination, corrosion and/or generation of a foreign substance originated from the production environment. In order to avoid these flaws, the standby time before advancing to the step of forming a diffusion-preventing film can be restricted; however, this is disadvantageous from the standpoints of the productivity and economic efficiency.

After the removal of excess copper wiring material by CMP method, in addition to completely removing contaminants, it is required to keep the surface of the copper wiring material clean until the subsequent step of forming a diffusion-preventing film because of the above-described problem caused by copper properties and the above-described disadvantage.

For removal of contamination caused by particles, an alkaline solution is known to be effective and an aqueous alkali solution such as ammonia, potassium hydroxide and tetramethyl ammonium hydroxide are conventionally used to clean the surfaces of silicon and silicon oxide substrates. Further, a cleaning liquid composition (called “SC-1” or “APM”) composed of ammonia, hydrogen peroxide and water is also widely used. However, APM and ammonia are highly corrosive to copper; therefore, it is difficult to apply APM and ammonia in the post-CMP cleaning of copper. In addition, although alkaline cleaning agents such as tetramethyl ammonium hydroxide (TMAH) generally have excellent particle-cleaning property, their metal contamination-removing ability is poor.

As a technology for removing particle contamination and metal contamination at the same time, Patent Document 1 proposes a cleaning liquid composition which comprises an organic alkali, a complexing agent and a surfactant in combination. However, in this technology, the protection performance to keep the copper wiring surface exposed after post-CMP cleaning clean was not sufficient (see Comparative Example 24).

As a copper surface-protecting film, Patent Documents 2 and 3 propose a treatment solution composed of an aqueous solution containing a C₃ to C₁₀ acetylene alcohol and state that a metal surface having no stain can be obtained because oxidation in the drying step is suppressed. However, a semiconductor production process where the inventions of these Patent Documents are applied assumes (1) after forming a copper wiring pattern or after performing a copper-CMP treatment and rinsing with water, a substrate on which a copper wiring pattern is formed prior to drying is treated with the aqueous solution of Patent Document 2 or 3, followed by drying; and (2) after performing a treatment using the aqueous solution of Patent Document 2 or 3 as a rinse solution, the resulting substrate is dried. Therefore, the inventions of Patent Documents 2 and 3 and the liquid composition for cleaning after CMP treatment according to the present invention are different in terms of the process where they are used. Further, since these technologies according to Patent Documents 2 and 3 cannot remove contaminants after CMP (Comparative Examples 6 and 7), there is a flaw in the application of the technologies to post-CMP cleaning. Moreover, in such an alkaline composition of the present invention, those acetylene alcohols mentioned as useful in these Patent Documents may not be able to provide protection performance to keep the exposed copper wiring surface clean (Comparative Examples 19 and 20).

Therefore, in the present art, it is extremely useful to provide a cleaning liquid composition for post-CMP cleaning which has low corrosivity to a substrate surface and is capable of removing contaminants remaining on the substrate surface after the above-described CMP and maintaining the copper surface exposed after cleaning clean.

### PRIOR ART DOCUMENTS

### Patent Documents

Patent Document 1: JP 2001-345303A
Patent Document 2: JP H10-8278A
Patent Document 3: JP 2002-164315A

### SUMMARY OF THE INVENTION

### Problems to be Solved by the Invention

An object of the present invention is to provide a liquid composition for post-CMP cleaning, which is, in the production of a semiconductor circuit device, used to clean a semiconductor substrate having a copper wiring material on the surface, particularly a semiconductor substrate having an exposed copper wiring material after chemical-mechanical polishing (CMP), by removing residual liquid and contaminants remaining on the substrate surface after CMP of the substrate surface and protecting the surface of the copper wiring material until just before the step of covering the copper wiring material with a diffusion-preventing film against deterioration such as corrosion, oxidation and generation of foreign substance and contamination originated from the production environment that occur in the steps of, for example, cleaning, washing with water and drying the surface of the copper wiring material exposed after cleaning or during the standby time between the steps, thereby obtaining a copper wiring material having clean surface. Another object of the present invention is to provide a method of producing a semiconductor substrate using the liquid composition.

### Means for Solving the Problems

In order to solve the above-described problems, the present inventors intensively studied to discover that, by using an aqueous solution comprising a quaternary ammonium hydroxide, 1-ethinyl-1-cyclohexanol which is a copper-protecting component, a complexing agent, diethylenetriamine pentamethylene phosphonate and water as a liquid composition for post-CMP cleaning, without corroding the materials constituting a semiconductor circuit device, residual liquid and contaminants remaining on the substrate surface after chemical-mechanical polishing (CMP) can be removed and the surface of the copper wiring material can be effectively protected against, for example, deterioration such as corrosion, oxidation and generation of foreign substance and contamination caused by the production environment; and that a copper wiring material having clean surface to which 1-ethinyl-1-cyclohexanol is not adhered can be obtained by performing a subsequent simple treatment, thereby completing the present invention.

That is, the present invention is as follows.

1. A cleaning liquid composition, which comprises 0.03 to 1.0% by weight of a quaternary ammonium hydroxide, 0.01 to 0.2% by weight of 1-ethinyl-1-cyclohexanol, 0.001 to 0.05% by weight of a complexing agent, 0.0001 to 0.002% by weight of diethylenetriamine pentamethylene phosphonate and water, the cleaning liquid composition having a pH of 9 to 13.
2. The cleaning liquid composition according to 1., wherein the above-described quaternary ammonium hydroxide is at least one selected from the group consisting of tetramethylammonium hydroxide (TMAH), tetraethylammonium hydroxide, trimethyl(hydroxyethyl)ammonium hydroxide and triethyl(hydroxyethyl)ammonium hydroxide.
3. The cleaning liquid composition according to 1. or 2., wherein the above-described complexing agent is at least one selected from the group consisting of catechol, pyrogallol and 4-t-butylpyrocatechol.
4. The cleaning liquid composition according to any one of 1. to 3., which further comprises 0.001% by weight to 20% by weight of a water-soluble organic solvent.
5. The cleaning liquid composition according to 4., wherein the above-described water-soluble organic solvent is at least one selected from the group consisting of diethylene glycol monobutyl ether and dipropylene glycol monomethyl ether.
6. A concentrated cleaning liquid composition, which comprises 0.1 to 10% by weight of a quaternary ammonium hydroxide, 0.1 to 5% by weight of 1-ethinyl-1-cyclohexanol, 0.01 to 1% by weight of a complexing agent, 0.001 to 0.1% by weight of diethylenetriamine pentamethylene phosphonate, 1 to 40% by weight of a water-soluble organic solvent and water.
7. The concentrated cleaning liquid composition according to 6., wherein the above-described quaternary ammonium hydroxide is at least one selected from the group consisting of tetramethylammonium hydroxide (TMAH), tetraethylammonium hydroxide, trimethyl(hydroxyethyl)ammonium hydroxide and triethyl(hydroxyethyl)ammonium hydroxide.
8. The concentrated cleaning liquid composition according to 6. or 7., wherein the above-described complexing agent is at least one selected from the group consisting of catechol, pyrogallol and 4-t-butylpyrocatechol.
9. The concentrated cleaning liquid composition according to any one of 6. to 8., wherein the above-described water-soluble organic solvent is at least one selected from the group consisting of diethylene glycol monobutyl ether and dipropylene glycol monomethyl ether.
10. A method of cleaning a semiconductor substrate, which comprises the steps of: subjecting a semiconductor substrate which has a wiring containing copper in an amount of not less than 80% to chemical-mechanical polishing (CMP); and subsequently cleaning the semiconductor substrate using the cleaning liquid composition according to any one of 1. to 5.
11. The method of cleaning a semiconductor substrate according to 10., which further comprises, before the above-described cleaning step, the step of 2-fold to 1.000-fold diluting the concentrated cleaning liquid composition according to any one of 6. to 9. with water to obtain the cleaning liquid composition according to any one of 1. to 5.

### EFFECTS OF THE INVENTION

By the cleaning liquid composition according to the present invention, in the step of cleaning a semiconductor substrate having a copper wiring in a semiconductor production process, particularly in the step of cleaning a semiconductor substrate having an exposed copper wiring after CMP, residual liquid and contaminants such as particles and metal impurities adhered to the substrate surface can be effectively removed without damaging the materials constituting a semiconductor circuit device. Further, the cleaning liquid composition according to the present invention is capable of protecting the surface of the copper wiring material until just before the step of covering the copper wiring material with a diffusion-preventing film against deterioration such as corrosion, oxidation and generation of foreign substance and contamination originated from the production environment that occur in the steps of, for example, cleaning, washing with water and drying the surface of the copper wiring material exposed after CMP or during the standby time between the steps, and the protective component can be removed by a simple treatment; therefore, it became possible to obtain a copper wiring material with clean surface.

### MODE FOR CARRYING OUT THE INVENTION

### Cleaning Liquid Composition

The present invention will now be described in detail. The cleaning liquid composition according to the present invention comprises a quaternary ammonium hydroxide, 1-ethinyl-1-cyclohexanol, a complexing agent, diethylenetriamine pentamethylene phosphonate and water. The cleaning liquid composition according to the present invention may further comprise a water-soluble organic solvent.

The cleaning liquid composition according to the present invention is a cleaning liquid composition which is used in the production of a semiconductor circuit device and other electronic devices to remove metal impurities and particulates adhered to the surface of a substrate having a copper wiring and in particular, a cleaning liquid composition which is used in the step of cleaning a semiconductor substrate having an exposed copper wiring after CMP. Further, the cleaning liquid composition according to the present invention can be applied not only to the above-described step of cleaning a semiconductor substrate having exposed copper wiring after CMP, but also to the step of removing dry-etching residue generated during the formation of damascene wiring.

The substrate to be cleaned by the cleaning liquid composition according to the present invention is one which is used in the production of a semiconductor and other electronic devices and has a copper wiring on the surface and in particular, a semiconductor substrate having an exposed copper wiring after CMP or a semiconductor substrate whose copper wiring is exposed at the time of dry-etching an insulating film in the formation of damascene wiring.

Specific examples of the quaternary ammonium hydroxide used in the cleaning liquid composition according to the present invention include tetramethylammonium hydroxide (abbreviated as “TMAH), tetraethylammonium hydroxide, trimethyl(hydroxyethyl)ammonium hydroxide (commonly called “choline”) and triethyl(hydroxyethyl)ammonium hydroxide. Thereamong, from the standpoints of the cleaning performance, economic efficiency, stability, odorlessness and the like, tetra methylammonium hydroxide (TMAH) and trimethyl(hydroxyethyl)ammonium hydroxide (choline) are particularly suitable. Further, depending on the use, the cleaning liquid composition according to the present invention may also comprise one or more quaternary ammonium hydroxides.

The concentration of the quaternary ammonium hydroxide(s) in the cleaning liquid composition is decided with considerations of the contaminant-cleaning property and the corrosivity to the material; however, it is preferably 0.03 to 1.0% by weight, more preferably 0.04 to 0.8% by weight, particularly preferably 0.05 to 0.5% by weight. As long as the concentration of the quaternary ammonium hydroxide(s) is not lower than 0.03% by weight, metals such as Fe and Cu can be sufficiently removed by cleaning, and as long as the concentration is not higher than 1.0% by weight, the corrosivity to the material (such as bare silicon) can be suppressed and the cost of chemical solution materials can be reduced.

The cleaning liquid composition according to the present invention comprises 1-ethinyl-1-cyclohexanol. The concentration of 1-ethinyl-1-cyclohexanol in the cleaning liquid composition is decided with considerations of the protection performance for copper and copper alloy, material corrosivity, economic efficiency and the like; however, it is preferably 0.01 to 0.2% by weight, more preferably 0.015 to 0.15% by weight, particularly preferably 0.02 to 0.10% by weight. As long as the concentration of 1-ethinyl-1-cyclohexanol is not lower than 0.01% by weight, the protection performance for Cu can be sufficiently ensured, and as long as the concentration is not higher than 0.2% by weight, the cost of chemical solution materials can be reduced.

Further, specific examples of the complexing agent used in the cleaning liquid composition according to the present invention include catechol, pyrogallol and 4-t-butylpyrocatechol and the complexing agent is more preferably catechol. The cleaning liquid composition according to the present invention may also comprise one or more of these complexing agents depending on the use thereof.

The concentration of the complexing agent(s) in the cleaning liquid composition is decided as appropriate with consideration of the metal contaminant-cleaning property; however, it is preferably 0.001 to 0.05% by weight, more preferably 0.002 to 0.04% by weight, still more preferably 0.002 to 0.03% by weight. As long as the concentration of the complexing agent(s) is not lower than 0.001% by weight, metals such as Fe and Cu can be sufficiently removed by cleaning, and as long as the concentration is not higher than 0.05% by weight, the protection performance for Cu can be sufficiently ensured.

In the cleaning liquid composition according to the present invention, in order to improve the ability to inhibit readhesion of metal contaminants, diethylenetriamine pentamethylene phosphonate (DTPP) is used. In order to further improve the readhesion-inhibiting ability, the cleaning liquid composition may also comprise glycine, ethylenediamine tetraacetic acid (EDTA) and ethylenediamine tetrakis(methylene phosphonic)acid (EDTPO).

The concentration of diethylenetriamine pentamethylene phosphonate in the cleaning liquid composition is decided as appropriate with considerations of the ability to inhibit readhesion of contaminants, economic efficiency and the like; however, it is preferably 0.0001 to 0.002% by weight, more preferably 0.0002 to 0.004% by weight, particularly preferably 0.0002 to 0.003% by weight. As long as the concentration of diethylenetriamine pentamethylene phosphonate is not lower than 0.0001% by weight, the metal readhesion-inhibiting ability can be improved, and as long as the concentration is not higher than 0.002% by weight, the cost of chemical solution materials can be reduced.

The pH value of the cleaning liquid composition according to the present invention is 9 to 13, preferably 11.5 to 13. As long as the pH value of the cleaning liquid composition is not lower than 9, an ability to remove metal impurities and particles adhered to the wafer surface and excellent copper protection ability can be demonstrated without corroding the copper wiring, and as long as the pH value is not higher than 13, the cost of chemical solution materials where a large amount of organic alkali is required can be reduced and the corrosivity against the substrate can be suppressed.

As the solvent used in the present invention, water is preferably employed; however, it is also effective to use as appropriate a mixture of a water-soluble alcohol and glycol ether.

As the alcohol, C₁ to C₁₀ alcohols are preferred and methanol, ethanol and isopropanol are suitable.

As the glycol ether, monoalkyl ethers and dialkyl ethers of ethylene glycol, diethylene glycol, triethylene glycol, propylene glycol, dipropylene glycol, tripropylene glycol and the like are preferred, and thereamong, diethylene glycol monoalkyl ethers, diethylene glycol dialkyl ethers, dipropylene glycol monoalkyl ethers, dipropylene glycol dialkyl ethers and the like are suitable. Specifically, diethylene glycol monomethyl ether, diethylene glycol monobutyl ether, dipropylene glycol monomethyl ether and the like, preferably dipropylene glycol monomethyl ether, can be suitably used because of the solubility of the components and high cleaning performance and protection performance of the resulting cleaning liquid composition.

The concentration of the water-soluble organic solvent in the cleaning liquid composition is decided as appropriate with considerations of the solubilities of the respective components, economic efficiency and the like; however, it is preferably 0.001 to 20% by weight, more preferably 0.01 to 10% by weight, still more preferably 0.1 to 5% by weight, particularly preferably 0.1 to 1% by weight.

### Concentrated Cleaning Liquid Composition

The cleaning liquid composition according to the present invention can be provided in the form of a concentrated cleaning liquid composition. That is, the concentrated cleaning liquid composition may be delivered in a highly concentrated form having a concentration of about 2 times to 1,000 times of that of the cleaning liquid composition and diluted to a desired concentration just before use. As a diluent, water is normally employed and distilled water and pure water are suitably employed. Further, such concentrated cleaning liquid composition is more easily transported and stored.

The concentrated cleaning liquid composition comprises 0.1 to 10% by weight of a quaternary ammonium hydroxide, 0.1 to 5% by weight of 1-ethinyl-1-cyclohexanol, 0.01 to 1% by weight of a complexing agent, 0.001 to 0.1% by weight of diethylenetriamine pentamethylene phosphonate, 1 to 40% by weight of a water-soluble organic solvent and water. This concentrated cleaning liquid composition can be used for cleaning by diluting it with water by 2-fold to 1.000-fold, preferably 2 to 500-fold, still more preferably 2 to 200-fold, particularly preferably 2 to 100-fold.

The concentrated cleaning liquid composition can be used for cleaning by diluting it with water by 2 to 1.000-fold such that the cleaning liquid composition diluted with water comprises 0.03 to 1.0% by weight of a quaternary ammonium hydroxide, 0.01 to 0.2% by weight of 1-ethinyl-1-cyclohexanol, 0.001 to 0.05% by weight of a complexing agent, 0.0001 to 0.002% by weight of diethylenetriamine pentamethylene phosphonate and 0.001% by weight to 20% by weight of a water-soluble organic solvent and has a pH of 9 to 13.

### Method of Cleaning Semiconductor Substrate

Examples of the method of cleaning a semiconductor substrate having a copper wiring, which is performed using the cleaning liquid composition according to the present invention after chemical-mechanical polishing, include batch-type cleaning in which the substrate is directly immersed in the cleaning liquid composition and single wafer cleaning in which the cleaning liquid composition is supplied to the substrate surface via a nozzle while spin-rotating the substrate. Further, physical cleaning methods such as brush-scrub cleaning with a sponge brush made of polyvinyl alcohol and megasonic cleaning with high frequency wave can be employed and for example, a method in which the above-described cleaning methods are combined may also be employed.

### EXAMPLES

The present invention will now be described more specifically by way of examples and comparative examples thereof. However, the present invention is not restricted to the following examples by any means.

### Verification of the Corrosivity to PE-TEOS, Copper (Cu), Tantalum (Ta), Tantalum Nitride (TaN) and Bare Silicon (Bare Si)

### (PE-TEOS: A Type of Silicon Oxide Film Formed by a Plasma CVD Method Using Tetraethoxysilane as a Material Gas)

### Examples 1 and 2 and Comparative Examples 1 to 3

The cleaning liquid compositions used in Examples 1 and Comparative Examples 1 to 3 were prepared in accordance with the respective compositions shown in Table 1. The pH of the thus prepared solutions was measured by a pH meter F-52 (manufactured by HORIBA Ltd.) calibrated with standard solutions having a pH of 4, 7 and 9. From this point on, the pH of cleaning liquid composition was measured in the same manner.

TABLE 1

| | TMAH | ECH | Catechol | DTPP | Water | |
|---|---|---|---|---|---|---|
| | [% by | [% by | [% by | [% by | [% by | |
| | weight] | weight] | weight] | weight] | weight] | pH |
| Example 1 | 0.2000 | 0.0833 | 0.0167 | 0.0017 | Remainder | 12.7 |
| Example 2 | 0.1000 | 0.0417 | 0.0083 | 0.0002 | Remainder | 12.1 |
| Comparative | 0.1% Aqueous ammonia | | | | | 11.3 |
| Example 1 | | | | | | |
| Comparative | APM (an aqueous solution obtained by mixing | | | | | 10.8 |
| Example 2 | 29% aqueous ammonia, 31% hydrogen peroxide | | | | | |
| | solution and water at a volume ratio of 1:1:5) | | | | | |
| Comparative | 1.2000 | 0.0417 | 0.0083 | 0.0002 | Remainder | 13.3 |
| Example 3 | | | | | | |

TMAH: tetramethylammonium hydroxide
ECH: 1-ethinyl-1-cyclohexanol
DTPP: diethylenetriamine pentamethylene phosphonate

Chips having a size of 2 cm×2 cm were cut out from a silicon wafer with a PE-TEOS film, a silicon wafer having a Cu-plated film after CMP, a silicon wafer with a tantalum film and a silicon wafer with a tantalum nitride film, and each chip was subjected to an immersion treatment at 25° C. for 60 minutes in the respective cleaning liquid compositions of Examples 1 and 2 and Comparative Examples 1 to 3 having the composition shown in Table 1. Then, the film thickness of before and after the treatment was measured using a film thickness meter to compare the etch rates of the cleaning liquid compositions for the PE-TEOS film, Cu-plated film after CMP, silicon wafer with a tantalum film and silicon wafer with a tantalum nitride film.

As the film thickness meter, n&k Analyzer 1280 manufactured by n&k Technology, Inc. was used for the silicon wafer with a PE-TEOS film and a fluorescent X-ray analyzer (SEA2110L manufactured by SII NanoTechnology Inc.) was used for the silicon wafer with a Cu-plated film after CMP, the silicon wafer with a tantalum film and the silicon wafer with a tantalum nitride film.

The results are shown in Table 2.

TABLE 2

| | | | | | Existence |
|---|---|---|---|---|---|
| | Etch rate [Å/min] | | | | of corrosion |
| | PE-TEOS | Cu | Ta | TaN | Bare Si |
| Example 1 | 0 | 0 | 0 | 0 | No |
| Example 2 | 0 | 0 | 0 | 0 | No |
| Comparative | 0 | 4 | 1 | 0 | No |
| Example 1 | | | | | |
| Comparative | 0 | 140 | 1 | 0 | No |
| Example 2 | | | | | |
| Comparative | 0 | 0 | 0 | 0 | Yes |
| Example 3 | | | | | |

A 2 cm×2 cm chip was cut out from a bare silicon wafer and immersed in 0.1% by weight aqueous fluoric acid solution at 25° C. for 1 minute to perform a pretreatment to remove an oxidized layer on the surface. Thereafter, the resulting chip was subjected to an immersion treatment at 25° C. for 30 minutes in the cleaning liquid compositions of Examples 1 and 2 and Comparative Examples 1 to 3 having the respective composition shown in Table 1. The specular surface was visually observed to verify the existence of corrosion. The results are shown in Table 2.

In the cleaning liquid compositions of Examples 1 and 2, none of PE-TEOS, copper, tantalum, tantalum nitride and bare silicon was corroded; however, in the aqueous ammonia and commercially available APM of Comparative Examples 1 and 2, copper was heavily corroded. In Comparative Example 3, corrosion of the bare silicon was observed after the immersion in the solution. The etch rate was defined as satisfactory when it was evaluated as 0 and the corrosion of the bare silicon was defined as satisfactory when there was no corrosion.

### Evaluation of Particle Contamination-Cleaning Property by Immersion

### Examples 3 to 5 and Comparative Examples 4 and 5

The cleaning liquid compositions used in Examples 3 to 5 and Comparative Examples 4 and 5 were prepared in accordance with the respective compositions shown in Table 3.

TABLE 3

| | Quaternary | | | | | | |
|---|---|---|---|---|---|---|---|
| | ammonium | | | | | | |
| | hydroxide | | ECH | Catechol | DTPP | Water | |
| | [% by weight] | | [% by weight] | [% by weight] | [% by weight] | [% by weight] | pH |
| Example 3 | TMAH | 0.1000 | 0.0833 | 0.0100 | 0.0017 | Remainder | 12.1 |
| Example 4 | TMAH | 0.1000 | 0.0417 | 0.0083 | 0.0002 | Remainder | 12.1 |
| Example 5 | Choline | 0.1000 | 0.0833 | 0.0100 | 0.0017 | Remainder | 11.8 |
| Comparative | — | — | — | 0.0100 | 0.0017 | Remainder | 4.2 |
| Example 4 | | | | | | | |
| Comparative | — | — | 0.0833 | 0.0100 | 0.0002 | Remainder | 5.0 |
| Example 5 | | | | | | | |

TMAH: tetramethylammonium hydroxide
ECH: 1-ethinyl-1-cyclohexanol
DTPP: diethylenetriamine pentamethylene phosphonate
Choline: trimethyl(hydroxyethyl)ammonium hydroxide

The ability to remove silica particles from a PE-TEOS film was evaluated as follows. Colloidal silica (PL-2L manufactured by Fuso Chemical Co., Ltd.; primary particle size=16 nm) was diluted with an aqueous sulfuric acid solution to prepare an aqueous solution containing 10% by weight of silica particle and 0.5% by weight of sulfuric acid. By immersing a silicon wafer with a PE-TEOS film, which was cut into a size of 2 cm×2 cm, in the thus obtained solution at 25° C. for 10 minutes, silica particles were allowed to adhered onto the surface of the PE-TEOS film for contamination. The resulting wafer surface was observed under a scanning electron microscope (HITACHI high-resolution field-emission scanning electron microscope S-4700) to evaluate the degree of adhesion of silica particles to the surface. After contaminating the PE-TEOS film surfaces with silica particles in the same manner, the resultants were each immersed in the respective solutions of Examples 3 to 5 and Comparative Examples 4 and 5 at 25° C. for 10 minutes in a shaker with shaking (75 revolutions/min). Thereafter, each wafer was rinsed with ultrapure water and dried and the degree of adhesion of silica particles to the thus treated surface was then evaluated under a scanning electron microscope. The results are shown in Table 4.

As a result, it is seen that the cleaning liquid composition containing no quaternary ammonium hydroxide cannot remove silica particles. An evaluation of 4 was defined as satisfactory.

TABLE 4

| | Degree of particle removal |
|---|---|
| Without cleaning | 1 |
| Example 3 | 4 |
| Example 4 | 4 |
| Example 5 | 4 |
| Comparative Example 4 | 2 |
| Comparative Example 5 | 2 |

[Judgment Criteria]

The number of particles adhered to an area of 9.0×12.5 μm:
4: 0 to 10 particles
3: 10 to 100 particles
2: 100 to 1,000 particles
1: 1,000 to 4,000 particles

### Evaluation of Metal Contamination-Cleaning Property by Immersion

### Examples 6 to 10 and Comparative Examples 6 to 13

The solutions of Examples 6 to 10 and Comparative Examples 6 to 13 were prepared in accordance with the respective compositions shown in Table 5.

TABLE 5

| | Quaternary | | | | | | | |
|---|---|---|---|---|---|---|---|---|
| | ammonium | | | | | | | |
| | hydroxide | | ECH | Complexing agent | | DTPP | Water | |
| | [% by weight] | | [% by weight] | [% by weight] | | [% by weight] | [% by weight] | pH |
| Example 6 | TMAH | 0.2000 | 0.0833 | Catechol | 0.0167 | 0.0017 | Remainder | 12.7 |
| Example 7 | TMAH | 0.1000 | 0.0417 | Catechol | 0.0083 | 0.0002 | Remainder | 12.1 |
| Example 8 | TMAH | 0.1000 | 0.0417 | Pyrogallol | 0.0083 | 0.0008 | Remainder | 12.0 |
| Example 9 | TMAH | 0.1000 | 0.0417 | t-Bu-pyrocatechol | 0.0083 | 0.0008 | Remainder | 12.1 |
| Example 10 | Choline | 0.2000 | 0.0833 | Catechol | 0.0167 | 0.0017 | Remainder | 12.1 |
| Comparative | 50 ppm of 3,5-dimethyl-1-hexyn-3-ol aqueous solution (dimethyl hexynol aqueous solution) | | | | | | | 6.8 |
| Example 6 | | | | | | | | |
| Comparative | 1,000 ppm of 1-ethinyl-1-cyclohexanol aqueous solution | | | | | | | 6.0 |
| Example 7 | | | | | | | | |
| Comparative | TMAH | 0.1000 | — | — | — | — | Remainder | 12.4 |
| Example 8 | | | | | | | | |
| Comparative | TMAH | 0.1000 | 0.0833 | — | — | — | Remainder | 12.4 |
| Example 9 | | | | | | | | |
| Comparative | TMAH | 0.1000 | 0.0833 | Citric acid | 0.0167 | — | Remainder | 12.3 |
| Example 10 | | | | | | | | |
| Comparative | TMAH | 0.1000 | 0.0833 | DTPA | 0.0167 | — | Remainder | 12.3 |
| Example 11 | | | | | | | | |
| Comparative | TMAH | 0.0167 | 0.0417 | Catechol | 0.0083 | 0.0008 | Remainder | 11.0 |
| Example 12 | | | | | | | | |
| Comparative | TMAH | 0.1000 | 0.0417 | Catechol | 0.0005 | 0.0002 | Remainder | 12.1 |
| Example 13 | | | | | | | | |

TMAH: tetramethylammonium hydroxide
ECH: 1-ethinyl-1-cyclohexanol
DTPP: diethylenetriamine pentamethylene phosphonate
t-Bu-pyrocatechol: 4-t-butylpyrocatechol
Choline: trimethyl(hydroxyethyl)ammonium hydroxide
DTPA: diethylenetriamine pentaacetate

An aqueous solution containing Ca, Cr, Fe, Ni, Cu and Zn at a concentration of 100 ppm was prepared and applied on a silicon wafer with a TEOS film using a spin coater to contaminate the wafer surface. The resulting wafer was cut into 4 sections of equal size. When the surface concentrations of Ca, Cr, Fe, Ni, Cu and Zn were measured for one of the thus obtained sections using a total-reflection fluorescent X-ray analyzer TREX610T (manufactured by Tecnos Japan Inc.), it was found that Ca, Cr, Fe, Ni, Cu and Zn each adhered to the wafer surface in an amount of about 4×10¹³ atoms/cm². The remaining sections were subjected to an immersion treatment in the solutions of Examples 6 to 10 and Comparative Examples 6 to 13 at 25° C. for 20 seconds. Then, each wafer was rinsed with running ultrapure water and dried by shaking off the ultrapure water, followed by measurement of the surface concentrations of Ca, Cr, Fe, Ni, Cu and Zn using a total-reflection fluorescent X-ray analyzer TREX610T (manufactured by Tecnos Japan Inc.). The results are shown in Table 6. In the cleaning liquid compositions of Examples 6 to 10, their metal-removing abilities were evaluated as 2 to 4 for the respective metals with none of the cleaning liquid compositions being evaluated to have a metal-removing ability of 1; however, the metal-removing abilities of the solutions of Comparative Examples were evaluated as 1 for one or more metals and the solutions of Comparative Examples thus had considerably inferior metal-removing abilities as compared to the solutions of Examples. An evaluation of 2 or better was defined as satisfactory.

TABLE 6

Metal-removing ability

| | Ca | Cr | Fe | Ni | Cu | Zn |
|---|---|---|---|---|---|---|
| Example 6 | 4 | 3 | 2 | 4 | 4 | 4 |
| Example 7 | 3 | 3 | 2 | 3 | 3 | 2 |
| Example 8 | 3 | 3 | 2 | 3 | 2 | 3 |
| Example 9 | 3 | 3 | 2 | 2 | 2 | 2 |
| Example 10 | 4 | 3 | 2 | 4 | 4 | 4 |
| Comparative Example 6 | 4 | 2 | 1 | 3 | 2 | 3 |
| Comparative Example 7 | 4 | 2 | 1 | 3 | 2 | 3 |
| Comparative Example 8 | 3 | 2 | 1 | 1 | 1 | 2 |
| Comparative Example 9 | 3 | 2 | 1 | 1 | 1 | 2 |
| Comparative Example 10 | 3 | 2 | 1 | 2 | 1 | 2 |
| Comparative Example 11 | 4 | 2 | 1 | 2 | 1 | 2 |
| Comparative Example 12 | 4 | 2 | 1 | 2 | 2 | 3 |
| Comparative Example 13 | 3 | 2 | 1 | 1 | 1 | 2 |

[Judgment Criteria]
4: The surface metal content after cleaning is below the lower detection limit to less than 1×10¹¹ atoms/cm²
3: The surface metal content after cleaning is 1×10¹¹ atoms/cm² to less than 1×10¹² atoms/cm²
2: The surface metal content after cleaning is 1×10¹² atoms/cm² to less than 1×10¹³ atoms/cm²
1: The surface metal content after cleaning is not less than 1×10¹³ atoms/cm²

### Evaluation of The Effect to Inhibit Readhesion of Metal Contamination

### Examples 11 to 13 and Comparative Examples 14 to 16

The solutions of Examples 11 to 13 and Comparative Examples 14 to 16 were prepared in accordance with the respective compositions shown in Table 7.

TABLE 7

| | TMAH | ECH | Complexing agent | | DTPP | Water | |
|---|---|---|---|---|---|---|---|
| | [% by weight] | [% by weight] | [% by weight] | | [% by weight] | [% by weight] | pH |
| Example 11 | 0.1000 | 0.0833 | Catechol | 0.0100 | 0.0017 | Remainder | 12.1 |
| Example 12 | 0.2000 | 0.0417 | Catechol | 0.0083 | 0.0008 | Remainder | 12.8 |
| Example 13 | 0.1000 | 0.0417 | Catechol | 0.0083 | 0.0002 | Remainder | 12.1 |
| Comparative | 0.1000 | 0.0833 | — | — | — | Remainder | 12.1 |
| Example 14 | | | | | | | |
| Comparative | 0.1000 | 0.0833 | Catechol | 0.01 | — | Remainder | 12.1 |
| Example 15 | | | | | | | |
| Comparative | 0.1000 | 0.0833 | Catechol | 0.01 | 0.00005 | Remainder | 12.0 |
| Example 16 | | | | | | | |

TMAH: tetramethylammonium hydroxide
ECH: 1-ethinyl-1-cyclohexanol
DTPP: diethylenetriamine pentamethylene phosphonate

In order to replicate a system in which metal ions are eluted from a metal-contaminated substrate surface into a cleaning liquid composition during cleaning operation, Ca, Cr, Fe, Ni, Cu and Zn were each added in an amount of 10 ppb to the respective solutions of Examples 11 to 13 and Comparative Examples 14 to 16. A silicon wafer with a PE-TEOS film was cut into 4 sections of equal size and immersed in each cleaning liquid composition at 25° C. for 5 minutes. Then, each wafer was rinsed with running ultrapure water and dried by shaking off the ultrapure water, followed by measurement of the surface concentrations of Ca, Cr, Fe, Ni, Cu, Zn and K using a total-reflection fluorescent X-ray analyzer TREX610T (manufactured by Tecnos Japan Inc.). The results are shown in Table 8.

In the cleaning liquid composition of Examples 11 to 13, the wafer surface had an extremely low content of metals adhered from the cleaning liquid composition to which metal ions of Ca, Cr, Fe, Ni, Cu and Zn were added; however, in the cleaning liquid compositions of Comparative Examples 14 to 16, adhesion of Ca was not sufficiently prevented. For all of the items, an evaluation of 3 or better was defined as satisfactory.

TABLE 8

inhibit readhesion of
metal contamination

| | Ca | Cr | Fe | Ni | Cu | Zn |
|---|---|---|---|---|---|---|
| Example 11 | 4 | 4 | 4 | 4 | 4 | 4 |
| Example 12 | 4 | 4 | 4 | 4 | 4 | 4 |
| Example 13 | 3 | 4 | 4 | 4 | 4 | 4 |
| Comparative Example 14 | 2 | 3 | 1 | 2 | 3 | 2 |
| Comparative Example 15 | 2 | 4 | 4 | 4 | 4 | 4 |
| Comparative Example 16 | 2 | 4 | 4 | 4 | 4 | 4 |

[Judgment Criteria]
4: The surface metal content after cleaning is below the lower detection limit 3: The surface metal content after cleaning is 1×10¹⁰ atoms/cm²
2: The surface metal content after cleaning is higher than 1×10¹⁰ atoms/cm² but less than 1×10¹¹ atoms/cm²
1: The surface metal content after cleaning is not less than 1×10¹¹ atoms/cm²

### Evaluations of Copper Protection Ability

### Examples 14 and 15 and Comparative Examples 17 to 26

The solutions of Examples 14 and 15 and Comparative Examples 17 to 26 were prepared in accordance with the respective compositions shown in Table 9.

As the copper protection ability of the solutions of Examples 14 and 15 and Comparative Examples 17 to 26,

Evaluation 1: Evaluation of the copper corrosivity, Evaluation 2: Evaluation of corrosion with carbonated water, Evaluation 3: Evaluation by exposure under high humidity and Evaluation 4: Evaluation of the detachment property of protection film were performed.

TABLE 9

| | TMAH | Anticorrosive agent | | Catechol | DTPP | Water | |
|---|---|---|---|---|---|---|---|
| | [% by weight] | [% by weight] | | [% by weight] | [% by weight] | [% by weight] | pH |
| Example 14 | 0.1000 | 1-ethinyl-1-cyclohexanol | 0.0833 | 0.0100 | 0.0017 | Remainder | 12.1 |
| Example 15 | 0.1000 | 1-ethinyl-1-cyclohexanol | 0.0417 | 0.0083 | 0.0002 | Remainder | 12.1 |
| Comparative | 0.1000 | — | — | — | — | Remainder | 12.1 |
| Example 17 | | | | | | | |
| Comparative | 0.1000 | 3,5-dimethyl-1-hexyn-3-ol | 0.1000 | — | — | Remainder | 12.1 |
| Example 18 | | | | | | | |
| Comparative | 0.1000 | 3-methyl-pentyn-3-ol | 0.2500 | — | — | Remainder | 12.1 |
| Example 19 | | | | | | | |
| Comparative | 0.1000 | 3-methyl-butyn-3-ol | 0.2500 | — | — | Remainder | 12.1 |
| Example 20 | | | | | | | |
| Comparative | 0.1000 | 3-methyl-pentyn-3-ol | 0.2500 | 0.0100 | — | Remainder | 12.0 |
| Example 21 | | | | | | | |
| Comparative | 0.1000 | 3-methyl-butyn-3-ol | 0.2500 | 0.0100 | — | Remainder | 12.0 |
| Example 22 | | | | | | | |
| Comparative | 0.1000 | 3-methyl-pentyn-3-ol | 0.2500 | 0.0100 | 0.0020 | Remainder | 12.0 |
| Example 23 | | | | | | | |
| Comparative | TMAH/HBED/Water = 100/100/Remainder (ppm) | | | | | | 10.8 |
| Example 24 | | | | | | | |
| Comparative | 0.1000 | 1-ethinyl-1-cyclohexanol | 0.0833 | 0.0600 | — | Remainder | 11.7 |
| Example 25 | | | | | | | |
| Comparative | 0.1000 | 1-ethinyl-1-cyclohexanol | 0.0050 | 0.0083 | 0.0002 | Remainder | 12.0 |
| Example 26 | | | | | | | |

TMAH: tetramethylammonium hydroxide
DTPP: diethylenetriamine pentamethylene phosphonate
HBED: N,N′-bis(2-hydroxybenzyl)ethylenediamine-N,N′-diacetic acid-hydrochloride hydrate

### Evaluations of Copper Protection Ability: Evaluation 1 Evaluation of Copper Corrosion

In order to evaluate the corrosivities of the cleaning liquid compositions against copper, a silicon wafer having a Cu-plated film after CMP (hereinafter, referred to as “wafer with a Cu film”) was immersed in the respective solutions of Examples and Comparative Examples shown in Table 9 at 25° C. for 2 minutes. The resulting silicon wafer was then rinsed with ultrapure water and dried by nitrogen blow to be observed under a scanning electron microscope. An evaluation of 2 was defined as satisfactory.

Evaluation 1: Evaluation of copper corrosion
2: No corrosion was observed on the copper surface.
1: Corrosion or foreign substance was observed on the copper surface.
   Evaluations of Copper Protection Ability: Evaluation 2—Evaluation of Corrosion with Carbonated Water

In order to evaluate the surface protection ability for copper, a wafer with a Cu film was immersed in the respective solutions of Examples and Comparative Examples shown in Table 9 at 25° C. for 2 minutes. Subsequently, the resulting wafer was rinsed with ultrapure water and dried by nitrogen blow. The wafer was then immersed in ultrapure water to which carbon dioxide was dissolved (specific resistance: not greater than 0.1 MΩ·cm; hereinafter, referred to as “carbonated water”) at 25° C. for 5 minutes and dried by nitrogen blow. The surface of the wafer with a Cu film treated with carbonated water in this manner was observed under a scanning electron microscope. When Cu of the sample surface was corroded, the protection ability was judged to be poor. For comparison, a wafer with a Cu film which was immersed in carbonated water in the same procedures as described in the above but not in a cleaning liquid composition was observed under a scanning electron microscope (Comparative Example 27). An evaluation of 2 was defined as satisfactory.

Evaluation 2—Evaluation of Corrosion with Carbonated Water
2: No corrosion was observed on the copper surface.
1: Corrosion was observed on the copper surface.

### Evaluations of Copper Protection Ability: Evaluation 3—Evaluation by Exposure Under High Humidity

In order to evaluate the deterioration-inhibiting effect for copper, a wafer with a Cu film was immersed in the respective solutions of Examples and Comparative Examples shown in Table 9 at 25° C. for 2 minutes. Subsequently, the resulting wafer was rinsed with ultrapure water and dried by nitrogen blow. The wafer was then exposed to the environment for 4 hours in a thermo-hygrostat (IW221A manufactured by Yamato Scientific Co., Ltd.) maintained at a temperature of 60° C. and a humidity of 60%. The surface of the wafer with a Cu film treated in this manner was observed under a scanning electron microscope and when a foreign substance was generated on the Cu surface, the effect to inhibit the deterioration of Cu surface was judged to be poor. For comparison, a wafer with a Cu film which was exposed in a thermo-hygrostat in the same procedures as described in the above without immersion in a cleaning liquid composition was observed under a scanning electron microscope (Comparative Example 27). An evaluation of 2 was defined as satisfactory.

Evaluation 3—Evaluation by Exposure Under High Humidity
2: No foreign substance was observed on the copper surface.
1: The copper surface was observed to have a foreign substance.

### Evaluations of Copper Protection Ability: Evaluation 4—Evaluation of the Detachment Property of Protection Film

In order to verify the detachment property of protection film from copper surface, a wafer with a Cu film was immersed in the respective solutions of Examples shown in Table 9 at 25° C. for 2 minutes. Subsequently, the resulting wafer was rinsed with ultrapure water and dried by nitrogen blow. After heat-treating the wafer under atmospheric pressure in Ar gas flow at 300° C. for 1 minute, the resulting wafer was immersed in carbonated water at 25° C. for 5 minutes and the Cu surface was observed under a scanning electron microscope. In cases where a protection film is removed from the copper surface by heating the copper film to which the protection film is adhered, corrosion of the copper surface is observed during a treatment with carbonated water. Therefore, in the Evaluation 2, no observed corrosion of copper was a preferred result; however, in a preferred result of the Evaluation 4, corrosion of copper is observed. An evaluation of 2 was defined as satisfactory.

Evaluation of the detachment of protection film
2: Corrosion was observed on the copper surface.
1: No corrosion was observed on the copper surface.

Table 10 summarizes the results of the evaluation tests performed by immersing a wafer with a Cu film in the respective cleaning liquid compositions of Examples 14 and 15 and Comparative Examples 17 to 26 shown in Table 9. It is noted here that the results of Comparative Example 27 were obtained by performing the Evaluations 2 and 3 with no treatment with a cleaning liquid composition. As shown in Table 10, it is understood that, in Examples 14 and 15 where the present invention was applied, the property to protect the surface of copper wiring material was excellent and the protective component was easily removed from the copper surface. In all of the items, an evaluation of 2 was defined as satisfactory.

TABLE 10

| | | | | Evaluation 4 |
|---|---|---|---|---|
| | | Evaluation 2 | Evaluation 3 | Evaluation of |
| | Evaluation 1 | Evaluation of | Evaluation by | detachment |
| | Evaluation of | corrosion with | exposure under | property of |
| | copper corrosion | carbonated water | high humidity | protection film |
| Example 14 | 2 | 2 | 2 | 2 |
| Example 15 | 2 | 2 | 2 | 2 |
| Comparative Example 17 | 2 | 1 | — | — |
| Comparative Example 18 | 2 | 1 | — | — |
| Comparative Example 19 | 2 | 1 | — | — |
| Comparative Example 20 | 2 | 1 | — | — |
| Comparative Example 21 | 2 | 1 | — | — |
| Comparative Example 22 | 2 | 1 | — | — |
| Comparative Example 23 | 2 | 1 | — | — |
| Comparative Example 24 | 2 | 1 | — | — |
| Comparative Example 25 | 2 | 1 | — | — |
| Comparative Example 26 | 2 | 1 | — | — |
| Comparative Example 27 | — | 1 | 1 | — |

### Evaluation of the Performance of Cleaning Liquid Composition Obtained by Diluting Concentrated Cleaning Liquid Composition

### Examples 16 to 18

The concentrated cleaning liquid compositions used in Examples 16 to 18 were prepared in accordance with the respective compositions shown in Table 11. Prepared were: a cleaning liquid composition obtained by 30-fold diluting the concentrated cleaning liquid composition of Example 16 with water (in Table 11, indicated as “water-diluted solution”); a cleaning liquid composition obtained by 60-fold diluting the concentrated liquid composition of Example 17 with water; and a cleaning liquid composition obtained by 6-fold diluting the concentrated liquid composition of Example 18. The pH of the thus prepared water-diluted solutions was measured using a pH meter F-52 manufactured by HORIBA Ltd.

TABLE 11

| | TMAH | ECH | Catechol | DTPP | MFDG | Water | |
|---|---|---|---|---|---|---|---|
| | [% by weight] | [% by weight] | [% by weight] | [% by weight] | [% by weight] | [% by weight] | pH |
| High-concentration solution | 3.00 | 2.50 | 0.30 | 0.05 | 20.00 | Remainder | — |
| of Example 16 | | | | | | | |
| High-concentration solution | 6.00 | 2.50 | 0.50 | 0.01 | 20.00 | Remainder | — |
| of Example 17 | | | | | | | |
| High-concentration solution | 1.20 | 0.50 | 0.09 | 0.01 | 4.00 | Remainder | — |
| of Example 18 | | | | | | | |
| Water-diluted solution of | 0.1000 | 0.0833 | 0.0100 | 0.0017 | 0.6667 | Remainder | 12.1 |
| Example 16 (30-fold) | | | | | | | |
| Water-diluted solution of | 0.1000 | 0.0417 | 0.0083 | 0.0002 | 0.3333 | Remainder | 12.1 |
| Example 17 (60-fold) | | | | | | | |
| Water-diluted solution of | 0.2000 | 0.0833 | 0.0150 | 0.0017 | 0.6667 | Remainder | 12.8 |
| Example 18 (6-fold) | | | | | | | |

TMAH: tetramethylammonium hydroxide
ECH: 1-ethinyl-1-cyclohexanol
DTPP: diethylenetriamine pentamethylene phosphonate
MFDG: dipropylene glycol monomethyl ether

The above-described cleaning liquid compositions (water-diluted solutions) were subjected to the following evaluations in the same manner as described in the above.
Verification of the corrosivity to PE-TEOS, copper (Cu), tantalum (Ta), tantalum nitride (TaN) and bare silicon (bare Si) (in Table 12 below, abbreviated as “corrosivity”)
Evaluation of the particle contamination-cleaning property by immersion (in Table 12 below, abbreviated as “particle contamination-cleaning property”)
Evaluation of the metal contamination-cleaning property by immersion (in Table 12 below, abbreviated as “metal contamination-cleaning property”)
Evaluation of the effect to inhibit readhesion of metal contamination (in Table 12 below, abbreviated as “inhibit readhesion of metal contamination”)
Evaluations of the copper protection ability (Evaluation 1—Evaluation of copper corrosion; Evaluation 2—Evaluation of corrosion with carbonated water; Evaluation 3—Evaluation by exposure under high humidity; and Evaluation 4—Evaluation of the detachment property of protection film (in Table 12 below, abbreviated as “copper protection property”)

The results were evaluated based on the judgment criteria shown in Table 12.

The judgment results are shown in Table 12. The water-diluted solutions of Examples 16 to 18 were satisfactory for all of the evaluation items.

TABLE 12

| | Evaluation items | | | | |
|---|---|---|---|---|---|
| | | Particle | Metal | Inhibit readhesion | Copper |
| | | contamination- | contamination- | of metal | protection |
| | Corrosivity | cleaning property | cleaning property | contamination | property |
| Water-diluted solution of | Satisfactory | Satisfactory | Satisfactory | Satisfactory | Satisfactory |
| Example 16 (30-fold) | | | | | |
| Water-diluted solution of | Satisfactory | Satisfactory | Satisfactory | Satisfactory | Satisfactory |
| Example 17 (60-fold) | | | | | |
| Water-diluted solution of | Satisfactory | Satisfactory | Satisfactory | Satisfactory | Satisfactory |
| Example 18 (6-fold) | | | | | |

[Judgment Criteria]

Evaluation criteria for corrosivity: Evaluated as satisfactory when the etch rate is 0 Å/min and there is no corrosion of bare silicon.

Evaluation criteria for particle contamination-cleaning property: Evaluated as satisfactory when a score of 4 is given based on the judgment criteria shown in Table 4.

Evaluation criteria for metal contamination-cleaning property: Evaluated as satisfactory when a score of 2 or better is given based on the judgment criteria shown in Table 6 for all of the contaminating metals.

Evaluation criteria for inhibition of readhesion of metal contamination: Evaluated as satisfactory when a score of 3 or better is given based on the judgment criteria shown in Table 8 for all of the contaminating metals.

Evaluation criteria for copper protection property: Evaluated as satisfactory when a score of 2 is given for all of the items concerning the evaluation of copper corrosion, evaluation of corrosion with carbonated water, evaluation by exposure under high humidity and evaluation of the detachment property of protection film.

### INDUSTRIAL APPLICABILITY

The cleaning liquid composition according to the present invention has low corrosivity to the surface of a semiconductor substrate and is capable of removing contaminants remaining on the substrate surface after CMP and maintaining the copper surface exposed after cleaning clean. In the present art, it is extremely useful to provide such cleaning liquid composition for post-CMP cleaning.

1. A cleaning liquid composition, comprising:
0.03 to 1.0% by weight of a quaternary ammonium hydroxide;
0.01 to 0.2% by weight of 1-ethinyl-1-cyclohexanol;
0.001 to 0.05% by weight of a complexing agent;
0.0001 to 0.002% by weight of diethylenetriamine pentamethylene phosphonate; and
water,
said cleaning liquid composition having a pH of 9 to 13.

2. The cleaning liquid composition according to claim 1, wherein said quaternary ammonium hydroxide is at least one selected from the group consisting of tetramethylammonium hydroxide (TMAH), tetraethylammonium hydroxide, trimethyl(hydroxyethyl)ammonium hydroxide and triethyl(hydroxyethyl)ammonium hydroxide.

3. The cleaning liquid composition according to claim 1, wherein said complexing agent is at least one selected from the group consisting of catechol, pyrogallol and 4-t-butylpyrocatechol.

4. The cleaning liquid composition according to claim 1, further comprising:
0.001% by weight to 20% by weight of a water-soluble organic solvent.

5. The cleaning liquid composition according to claim 4, wherein said water-soluble organic solvent is at least one selected from the group consisting of diethylene glycol monobutyl ether and dipropylene glycol monomethyl ether.

6. A concentrated cleaning liquid composition, comprising:
0.1 to 10% by weight of a quaternary ammonium hydroxide;
0.1 to 5% by weight of 1-ethinyl-1-cyclohexanol;
0.01 to 1% by weight of a complexing agent;
0.001 to 0.1% by weight of diethylenetriamine pentamethylene phosphonate;
1 to 40% by weight of a water-soluble organic solvent; and
water.

7. The concentrated cleaning liquid composition according to claim 6, wherein said quaternary ammonium hydroxide is at least one selected from the group consisting of tetramethylammonium hydroxide (TMAH), tetraethylammonium hydroxide, trimethyl(hydroxyethyl)ammonium hydroxide and triethyl(hydroxyethyl)ammonium hydroxide.

8. The concentrated cleaning liquid composition according to claim 6, wherein said complexing agent is at least one selected from the group consisting of catechol, pyrogallol and 4-t-butylpyrocatechol.

9. The concentrated cleaning liquid composition according to claim 6, wherein said water-soluble organic solvent is at least one selected from the group consisting of diethylene glycol monobutyl ether and dipropylene glycol monomethyl ether.

10. A method of cleaning a semiconductor substrate, the method comprising:
chemical-mechanical polishing a semiconductor substrate which has a wiring comprising copper in an amount of not less than 80%; and
subsequently cleaning said semiconductor substrate with the cleaning liquid composition according to claim 1.

11. The method of claim 10, further comprising:
before said cleaning, diluting a concentrated cleaning liquid composition 2-fold to 1,000-fold with water to obtain a diluted cleaning liquid composition,
wherein:
the concentrated cleaning liquid composition comprises:
0.1 to 10% by weight of a quaternary ammonium hydroxide;
0.1 to 5% by weight of 1-ethinyl-1-cyclohexanol;
0.01 to 1% by weight of a complexing agent;
0.001 to 0.1% by weight of diethylenetriamine pentamethylene phosphonate;
1 to 40% by weight of a water-soluble organic solvent; and
water;
the diluted cleaning liquid composition comprises:
0.03 to 1.0% by weight of a quaternary ammonium hydroxide;
0.01 to 0.2% by weight of 1-ethinyl-1-cyclohexanol;
0.001 to 0.05% by weight of a complexing agent;
0.0001 to 0.002% by weight of diethylenetriamine pentamethylene phosphonate; and
water; and
the diluted cleaning liquid composition has a pH of 9 to 13.

12. The cleaning liquid composition according to claim 2, wherein said complexing agent is at least one selected from the group consisting of catechol, pyrogallol and 4-t-butylpyrocatechol.

13. The cleaning liquid composition according to claim 2, further comprising:
0.001% by weight to 20% by weight of a water-soluble organic solvent.

14. The cleaning liquid composition according to claim 13, wherein said water-soluble organic solvent is at least one selected from the group consisting of diethylene glycol monobutyl ether and dipropylene glycol monomethyl ether.

15. The concentrated cleaning liquid composition according to claim 7, wherein said complexing agent is at least one selected from the group consisting of catechol, pyrogallol and 4-t-butylpyrocatechol.

16. The concentrated cleaning liquid composition according to claim 15, wherein said water-soluble organic solvent is at least one selected from the group consisting of diethylene glycol monobutyl ether and dipropylene glycol monomethyl ether.

17. A method of cleaning a semiconductor substrate, the method comprising:
chemical-mechanical polishing a semiconductor substrate which has a wiring comprising copper in an amount of not less than 80%; and
subsequently cleaning said semiconductor substrate with the cleaning liquid composition according to claim 2.

18. The method of claim 17, further comprising:
before said cleaning, diluting a concentrated cleaning liquid composition 2-fold to 1.000-fold with water to obtain a diluted cleaning liquid composition,
wherein:
the concentrated cleaning liquid composition comprises:
0.1 to 10% by weight of a quaternary ammonium hydroxide;
0.1 to 5% by weight of 1-ethinyl-1-cyclohexanol;
0.01 to 1% by weight of a complexing agent;
0.001 to 0.1% by weight of diethylenetriamine pentamethylene phosphonate;
1 to 40% by weight of a water-soluble organic solvent; and
water;
the diluted cleaning liquid composition comprises:
0.03 to 1.0% by weight of a quaternary ammonium hydroxide;
0.01 to 0.2% by weight of 1-ethinyl-1-cyclohexanol;
0.001 to 0.05% by weight of a complexing agent;
0.0001 to 0.002% by weight of diethylenetriamine pentamethylene phosphonate; and
water; and
the diluted cleaning liquid composition has a pH of 9 to 13.
